(19) United States
(12) Patent Application Publication
(10) Pub. No.: US 2007/0176284 A1
(43) Pub. Date: Aug. 2, 2007

(54) Multi stack package with package lid

(75) Inventor: Jun-Young Choi, Seoul (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/652,551

(22) Filed: Jan. 12, 2007

(30) Foreign Application Priority Data
Jan. 31, 2006 (KR) 10-2006-0009392

(51) Int. Cl. H01L 23/34

(52) U.S. Cl. 257/718

(57) ABSTRACT

A multi stack package with a package lid may be provided. In the multi stack package, the package lid, which may be positioned on an upper part of a semiconductor package module of the stacked semiconductor package modules, may include a device to improve the electrical performance such as the signal transferring quality of semiconductor chips. The device may be inside or on a surface of the printed circuit board core forming the package lid. The devices, which may be formed on the semiconductor package module substrate in a conventional multi stack package, may be included in the package lid, thereby securing a region for circuit design on the semiconductor package module substrate.

### PRIORITY STATEMENT

This application claims the benefit of priority to Korean Patent Application No. 10-2006-0009392, filed on Jan. 31, 2006, in the Korean Intellectual Property Office, the entire contents of which is incorporated herein in its entirety by reference.

### BACKGROUND

1. Field

Example embodiments relate to a semiconductor package, and more particularly, to a multi stack package with a package lid, which may include a plurality of stacked semiconductor packages.

2. Description of Related Art

A semiconductor apparatus has been developed for higher-capacity, multi-functionality, miniaturization and to be lighter-weight, and a multi stack package (MSP) for forming a plurality of semiconductor packages as a single package may be generally used. A multi stack package may be defined as a structure in which individually assembled and test-completed semiconductor packages may be stacked, for example vertically.

FIG. 1 is a cross-sectional view of a conventional multi stack package. In FIG. 1, at least two fine ball grid array (FBGA) package modules 10 may be stacked to form the multi stack package. In each package module 10, a semiconductor die 12 may be attached to the surface of a package module substrate 16 by a die attachment pad 14, and a bonding pad (not shown) of the semiconductor die 12 may be electrically connected to a bonding pad (not shown) of the package module substrate 16 by a bonding wire 18. One package module 10 may be stacked on another package module 10 by at least one conductive bump 19, and the bottommost package module 10 may be connected to a substrate of another system by at least one conductive bump 19. A protection lid (not shown) may be mounted for protecting the uppermost package module 10 from external impact.

To improve the signal transferring quality of semiconductor chips, passive devices such as inductors, capacitors or resistors may be electrically connected to the package module substrate on which the semiconductor die may be mounted. For example, when a capacitor is connected to the package module substrate, cross talk occurring due to switching signals may be removed. The passive device may be mounted on the surface of the package module substrate by soldering, or it may be embedded in the package module substrate layer. However, as a semiconductor package becomes smaller, when a region of a printed circuit board is assigned for the passive devices, a region for circuit design available on the package module substrate is reduced.

### SUMMARY

Example embodiments may provide a package lid and/or a multi stack package to protect semiconductor chips from external impact and to secure a region for circuit design on a semiconductor package module substrate.

According to an example embodiment there may be a multi stack package comprising a plurality of stacked semiconductor package modules; and a package lid on the plurality of stacked semiconductor package modules, the package lid including a device.

According to an example embodiment, there may be a package lid including a device inside the package lid; a printed circuit board core; and a connection pad on a surface of the printed circuit board core, wherein the device is electrically connected to the connection pad.

According to an example embodiment, the device may be a passive device.

According to an example embodiment, the passive device may be at least one of a capacitor, an inductor, and a resistor.

According to an example embodiment, the device may be a package circuit.

According to an example embodiment, the package lid may be electrically connected to an uppermost semiconductor package module of the plurality of stacked semiconductor package modules.

According to an example embodiment, the package lid may have an area the same as or greater than the area of an uppermost semiconductor package module of the plurality of stacked semiconductor package modules.

According to an example embodiment, the package lid may include a printed circuit board.

According to an example embodiment the package lid may include an external connection pad and the device may be electrically connected to the connection pad.

According to an example embodiment, the device may be inside the package lid.

According to an example embodiment, each of the semiconductor package modules of the plurality of stacked semiconductor package modules may include a semiconductor die; and a package module substrate where the semiconductor die may be attached to the surface thereof, and electrically connected to the semiconductor die.

According to an example embodiment the semiconductor die may be electrically connected to the package module substrate by wire bonding.

According to an example embodiment, the semiconductor die may be electrically connected to the package module substrate by a flip-chip method.

According to an example embodiment, the package module substrate may include at least one connection pad, and the plurality of stacked semiconductor package modules may be electrically connected to each other by a stack element connecting the at least one connection pad of the package module substrate.

According to an example embodiment, the stack element may be a conductive bump.

According to an example embodiment the package lid may include a printed circuit board core; and a connection pad formed on either surface of the printed circuit board core, wherein the device is electrically connected to the connection pad.

According to an example embodiment, the package lid may further include a protecting layer on the upper and lower surfaces of the printed circuit board core, except for on a portion of a surface of the printed circuit board core that is connected to a surface of the connection pad; and a stack element connected to the connection pad.

According to an example embodiment, the device may be inside the printed circuit board core.

According to an example embodiment, the device may be on the surface of the printed circuit board core where the connection pad may be located.

According to an example embodiment, the device may be on the opposite surface to the surface of the printed circuit board core where the connection pad may be located.

According to an example embodiment, the protecting layer may be a resist.

According to an example embodiment, the connection pad may be connected to a conductive bump.

According to an example embodiment, the protecting layer may completely cover the device.

According to an example embodiment, when the device may be on the opposite surface to the surface of the printed circuit board core where the connection pad may be located, the device may be electrically connected to the connection pad by a contact penetrating the printed circuit board core.

### BRIEF DESCRIPTION OF THE DRAWINGS

The above and/or other aspects and advantages will become more apparent and more readily appreciated from the following detailed description of example embodiments taken in conjunction with the accompanying drawings of which:

FIG. 1 is a cross-sectional view of a conventional multi stack package;

FIG. 2 is a cross-sectional view of a multi stack package with a package lid according to an example embodiment;

FIG. 3 is a cross-sectional view of a package lid according to an example embodiment;

FIG. 4 is a cross-sectional view of a package lid according to another example embodiment; and

FIG. 5 is a cross-sectional view of a package lid according to another example embodiment.

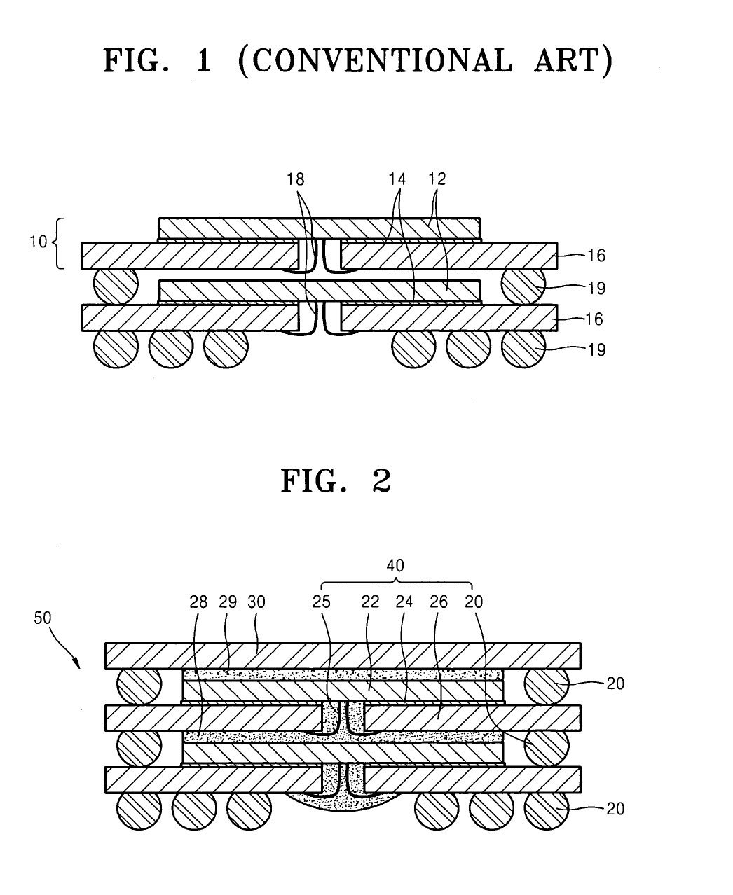

### DETAILED DESCRIPTION OF EXAMPLE EMBODIMENTS

Example embodiments will now be described more fully with reference to the accompanying drawings. Embodiments may, however, be embodied in many different forms and should not be construed as being limited to the example embodiments set forth herein. Rather, these example embodiments are provided so that this disclosure will be thorough and complete, and will fully convey the scope to those skilled in the art. In the drawings, the thickness of layers and regions may be exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

A multi stack package with a package lid according to an example embodiment will be described; and then a package lid according to example embodiments will be described.

FIG. 2 is a cross-sectional view of a multi stack package 50 with a package lid according to example embodiments. The multi stack package 50 of the example embodiments may be a stack package of a fine ball grid array (FBGA) package module. Referring to FIG. 2, the multi stack package 50 may include a plurality of stacked semiconductor package modules 40, and a package lid 30 on the uppermost semiconductor package module 40. Each semiconductor package module 40 may include a semiconductor die 22, a package module substrate 26, an adhesive material 24 such as an adhesive for attaching the semiconductor die 22 to the package module substrate 26, a bonding wire 25, and a stack element, for example, at least one conductive bump 20, for example a solder ball.

The semiconductor die 22 may be attached to the package module substrate 26 by the adhesive material 24, and may be electrically connected to the package module substrate 26 by the wire bonding 25. In an example embodiment, the semiconductor die 22 may be electrically connected to the package module substrate 26 by a flip-chip method using a bump (not shown). The package module substrate 26 may be a printed circuit board. A connection pad (not shown) may be formed on the upper and lower surfaces of the package module substrate 26, and may transfer an electric signal from or to the semiconductor die 22. The semiconductor package modules 40 may be electrically and/or mechanically connected to each other by the at least one conductive bump 20 connected to the connection pad (not shown). A buffer layer 28 may be formed between the semiconductor package modules 40 connected to each other by the at least one conductive bump 20, to reduce the thermal and/or mechanical stress of the multi stack package 50. The multi stack package 50 may be connected to printed circuit boards of different systems, by the at least one conductive bump 20 formed on the lower surface of the package module substrate 26 of the uppermost semiconductor package module 40.

The package lid 30 may be on the uppermost semiconductor package module 40. The package lid 30 may be attached on the uppermost semiconductor package module 40, by a buffer layer 29, for example, an adhesive, and may be electrically connected to the uppermost semiconductor package module 40 by the at least one conductive bump 20. The package lid 30 physically protects the uppermost semiconductor package module 40. The package lid 30 may have an area the same as or greater than the area of the uppermost semiconductor package module 40. Passive devices or other circuits, for example, a metal plate for transferring signals, may be formed at the package lid 30. As a semiconductor package becomes miniaturized, the region assigned for the passive elements or other circuits acceptable on the package module substrate 26 may be reduced. When the passive devices or other circuits for improving the electrical characteristics of a semiconductor apparatus are formed at the package lid 30, a region for other package circuits may be sufficiently secured on the package module substrate 26.

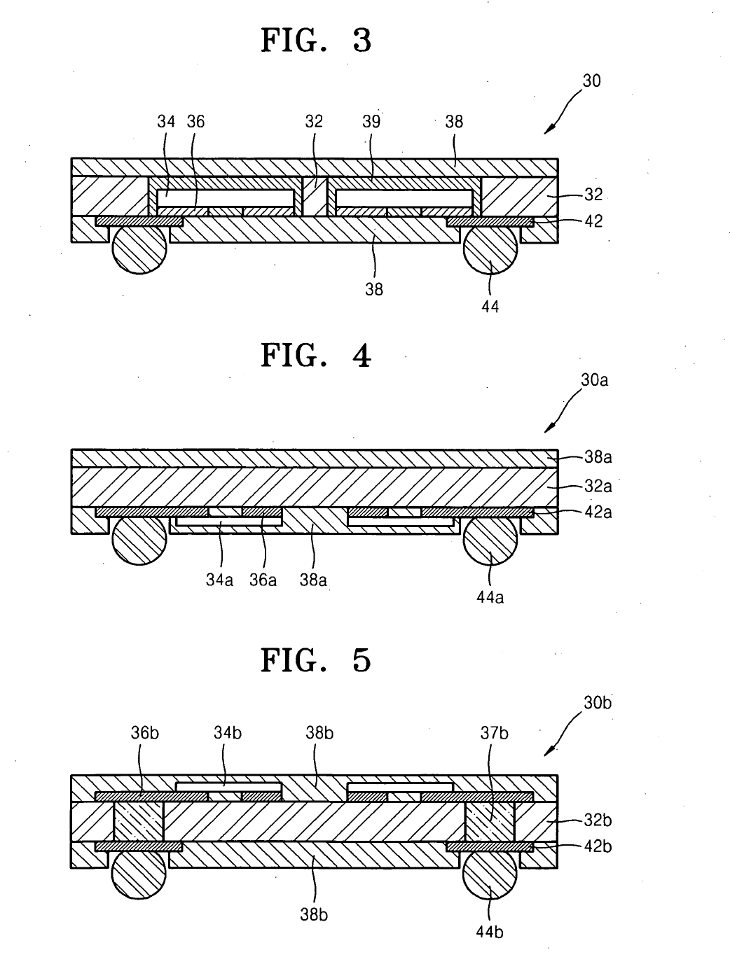

FIG. 3 is a cross-sectional view of the package lid 30 according to an example embodiment. The package lid 30 may include a printed circuit board. Referring to FIG. 3, a passive device, for example a capacitor 34, or another circuit, may be mounted in the space inside a printed circuit board core 32. Except for the portion where the capacitor 34 may be mounted, the printed circuit board core 32 may be filled with an insulating material 39. As a metal pattern 36 contacting the capacitor 34 comes into contact with part of a connection pad 42 positioned at the lower surface of the printed circuit board core 32, the capacitor 34 may be electrically connected to the connection pad 42. The connection pad 42 may be connected to at least one conductive bump 44, for example a solder ball, connected to the semiconductor package module (not shown). The package lid 30 may be electrically connected to the semiconductor package module by the at least one conductive bump 44. A resist 38, for example a solder resist, may protect the outside of the printed circuit board core 32.

FIG. 4 is a cross-sectional view of a package lid 30a according to another example embodiment. Like the package lid 30 of the example embodiment illustrated in FIG. 3, the package lid 30a may include a printed circuit board. A passive device, for example a capacitor 34a, or another circuit, may be positioned under a connection pad 42a formed on the lower surface of a printed circuit board core 32a. Because the capacitor 34a may be formed under the printed circuit board core 32a facing a semiconductor package module (not shown), the capacitor 34a may be less affected by external impact. The capacitor 34a may be electrically connected to the connection pad 42a formed on the lower surface of the printed circuit board core 32a, by a metal pattern 36a contacting the capacitor 34a. The metal pattern 36a and the connection pad 42a may be connected to each other on the same level of the lower surface of the printed circuit board core 32a. The upper and lower surfaces of the printed circuit board core 32a, except for the portion connected to the semiconductor package module 40a by at least one conductive bump 44a, may be protected by a resist 38a, for example a solder resist. The capacitor 34a under the printed circuit board core 32a may also be protected by the resist 38a.

FIG. 5 is a cross-sectional view of a package lid 30b according to another example embodiment. Like the package lids of the example embodiments in FIGS. 3 and 4, the package lid 30b may include a printed circuit board. A passive device, for example a capacitor 34b, or another circuit, may be positioned on the upper surface of a printed circuit board core 32b, and at least one conductive bump 44b may be positioned under the lower surface of the printed board core 32. The capacitor 34b may be connected to a connection pad 42b, by a contact 37b connected to a metal pattern 36b contacting the capacitor 34b and penetrating the printed circuit board core 32b. The upper and lower surfaces of the printed circuit board core 32b, except for the portion connected to a semiconductor package module (not shown) by the at least one conductive bump 44b, may be protected by a resist 38b. The capacitor 34b above the printed circuit board core 32b may also be protected by the resist 38b.

According to example embodiments, the package lid which protects the uppermost semiconductor package module in the multi stack package may include the passive devices or other package circuits which improve the electrical performance, for example the signal transferring quality of semiconductor chips, thereby securing a region for circuit design on the semiconductor package module substrate.

Although example embodiments have been shown and described in this specification and figures, it would be appreciated by those skilled in the art that changes may be made to the illustrated and/or described example embodiments without departing from their principles and spirit, the scope of which is defined by the claims and their equivalents.

What is claimed is:

1. A multi stack package comprising:
a plurality of stacked semiconductor package modules; and
a package lid on the plurality of stacked semiconductor package modules, the package lid including a device.

2. The multi stack package of claim 1, wherein the device is a passive device.

3. The multi stack package of claim 2, wherein the passive device is at least one of a capacitor, an inductor and a resistor.

4. The multi stack package of claim 1, wherein the device is a package circuit.

5. The multi stack package of claim 1, wherein the package lid is electrically connected to an uppermost semiconductor package module of the plurality of stacked semiconductor package modules.

6. The multi stack package of claim 1, wherein the package lid has an area the same as or greater than an area of an uppermost semiconductor package module of the plurality of stacked semiconductor package modules.

7. The multi stack package of claim 1, wherein the package lid further includes a printed circuit board.

8. The multi stack package of claim 1, wherein the package lid further includes an external connection pad, and the device is electrically connected to the external connection pad.

9. The multi stack package of claim 1, wherein the device is inside the package lid.

10. The multi stack package of claim 1, wherein each of the semiconductor package modules of the plurality of stacked semiconductor package modules further includes
a semiconductor die; and
a package module substrate, where the semiconductor die is attached to a surface thereof, and electrically connected to the semiconductor die.

11. The multi stack package of claim 10, wherein the semiconductor die is electrically connected to the package module substrate by a bonding wire.

12. The multi stack package of claim 10, wherein the semiconductor die is electrically connected to the package module substrate by a flip-chip method.

13. The multi stack package of claim 10, wherein the package module substrate includes at least one connection pad, and the plurality of stacked semiconductor package modules are electrically connected to each other by a stack element connecting the at least one connection pad of each of the package module substrates.

14. The multi stack package of claim 13, wherein the stack element is a conductive bump.

15. The multi stack package of claim 1, wherein the package lid further includes
a printed circuit board core; and
a connection pad on a surface of the printed circuit board core, wherein the device is electrically connected to the connection pad.

16. The multi stack package of claim 15, wherein the package lid further includes a protecting layer on upper and lower surfaces of the printed circuit board core, except for on a portion of a surface of the printed circuit board core that is connected to a surface of the connection pad; and
a stack element connected to the connection pad.

17. The multi stack package of claim 15, wherein the device is inside the printed circuit board core.

18. The multi stack package of claim 15, wherein the device is on the surface of the printed circuit board core where the connection pad is located.

19. The multi stack package of claim 15, wherein the device is on the opposite surface to the surface of the printed circuit board core where the connection pad is located.

20. The multi stack package of claim 16, wherein the protecting layer is a resist.

21. The multi stack package of claim 16, wherein the protecting layer completely covers the device.

22. The multi stack package of claim 19, wherein the device is electrically connected to the connection pad by a contact penetrating the printed circuit board core.

23. A package lid including:
a device inside the package lid;
a printed circuit board core;
a connection pad on a surface of the printed circuit board core, wherein the device is electrically connected to the connection pad.

24. The package lid of claim 23, wherein the device is a passive device.

25. The package lid of claim 24, wherein the passive device is at least one of a capacitor, an inductor, and a resistor.

26. The package lid of claim 23, wherein the device is a package circuit.

27. The package lid of claim 23, the package lid further including:
a protecting layer on upper and lower surfaces of the printed circuit board core, except for on a portion of a surface of the printed circuit board core that is connected to a surface of the connection pad.

28. The package lid of claim 27, wherein the protecting layer is a resist.

29. The package lid of claim 23, wherein the connection pad is connected to a conductive bump.

30. The package lid of claim 23, wherein the device is inside the printed circuit board core.

31. The package lid of claim 23, wherein the device is on the surface of the printed circuit board core where the connection pad is located.

32. The package lid of claim 23, wherein the device is on the opposite surface to the surface of the printed circuit board core where the connection pad is located.

33. The package lid of claim 32, wherein the device is electrically connected to the connection pad by a contact penetrating the printed circuit board core.
